(19) United States
(12) Patent Application Publication
(10) Pub. No.: US 2024/0176926 A1
(43) Pub. Date: May 30, 2024

(54) METHOD AND SYSTEM FOR SIMULATING A CONTROL PROGRAM

(71) Applicant: dSPACE GmbH, Paderborn (DE)

(72) Inventors: Oliver WAGNER, Paderborn (DE); Siamak ARIFY, Paderborn (DE)

(73) Assignee: dSPACE GmbH, Paderborn (DE)

(21) Appl. No.: 18/070,968

(22) Filed: Nov. 29, 2022

(51) Int. Cl. G06F 30/20; G05B 17/02

(52) U.S. Cl. CPC G06F 30/20; G05B 17/02

(57) ABSTRACT

A computer-implemented method and system for simulating a program modeled as one or more blocks of a block diagram in a computing environment. The one or more blocks having at least one signal, the computing environment including a model editor, a data definition tool and a code generator. The method includes: Simulating the block diagram for a first time span in the simulation environment, Displaying the values of the signal as a function of the simulation time, Receiving a pause command at a specific simulation time and a new value for the parameter, Simulating the block diagram for a second time span in the simulation environment, and Displaying both the values of the signal from the first time span and the values of the signal from the second time span. The values from the second time span are displayed graphically different from those of the first time span.

### BACKGROUND OF THE INVENTION

### Field of the Invention

The present invention relates to a method and computer system for automatically generating code from block diagrams, the code preferably being used in electronic control units.

### Description of the Background Art

Electronic control units (abbreviated as ECUs) are ubiquitous especially in automotive applications; generally, they may contain a processor, in particular a microcontroller, one or more sensor interfaces and one or more circuits to control an actuator. Current parameters of a physical process are preferably determined using the signals of the one or more sensors connected to the sensor interfaces. Based on a predefined control strategy, the processor may control the one or more circuits to apply the actuators in order to influence the physical process. For example, an ECU may be used to perform anti-lock braking, with a sensor measuring the wheel velocity and a magnetic valve reducing the pressure in the corresponding wheel brakes.

To speed up the development process for ECUs, control strategies are often developed using block diagrams in a technical computing environment (abbreviated as TCE) such as MATLAB/Simulink. Therefore, the process and/or the controller, or the behavior of the ECU in general, can be simulated first and it can be checked whether desired properties are present. In particular, the models may be block diagrams comprising blocks that execute operations such as calculations; by way of example, a block may calculate one output signal from a plurality of input signals. In general, block diagrams are executed cyclically, with all blocks being permanently retained in the memory and each block being executed once per time step. In particular, in each time step a block may apply one or more operations to input signals from the parent block in order to generate output signals for the current step. Block diagrams may additionally comprise a sub-model for describing a discrete behavior in which a number of states and transition conditions are defined.

Source code for programming the ECU can be generated from the models using a code generator. The document “Production Quality Code Generation from Simulink Block Diagrams”, Proceedings of the 1999 IEEE International Symposium on Computer Aided Control System Design, Kohala-Coast, Hawai'i, USA, by H. Hanselmann et al. describes a system for automatically generating production code based on a block diagram containing one or more blocks that specify the functionality of the program.

When perfecting the model for a desired behavior of the ECU, a multitude of simulations need to be carried out. Using prepared sets of input data, running a simulation may be done automatically via scripts. However, existing simulation methods are poorly adapted to fine-tuning individual parameters.

Thus, improved methods for simulating models for control programs are needed; in particular, it would be desirable to facilitate visually comparing the influence of different parameter settings.

### SUMMARY OF THE INVENTION

It is therefore an object of the present invention to provide a method and computer system for automatically generating source code from a block diagram comprising a detailed implementation of the program.

In a first aspect of the invention, a computer-implemented method for simulating a program is provided, the program being modeled as a plurality of blocks in a block diagram, the block diagram comprising at least one signal emitted by one of the blocks and at least one parameter that influences a value of the signal, the block diagram being executed in a technical computing environment, the technical computing environment comprising a model editor and a simulation environment. The method can comprise: Opening the block diagram in the model editor; Simulating the block diagram for a first time span in the simulation environment, comprising periodically executing at least some of the blocks and periodically logging a current value of the signal; Displaying the values of the signal as a function of the simulation time; Receiving a pause command at a specific simulation time; Receiving a new value for the at least one parameter; Simulating the block diagram for a second time span in the simulation environment, comprising periodically executing at least some of the blocks and periodically logging a current value of the signal; and/or Displaying both the values of the signal from the first time span and the values of the signal from the second time span, wherein the values from the second time span are displayed graphically different from those of the first time span.

Displaying the values of two signals graphically different can mean that each signal is displayed in a different color and/or each signal is displayed in a different line style and/or each signal is displayed using different symbols for individual data points. For example, the signal values from a previous simulation run are always displayed, and new data points are added for the running simulation based on current signal values. Markers may be created automatically, to indicate points in simulation time when a parameter value has been made to change the simulation behavior. The markers can be displayed in the plot of the signal values.

The steps of the inventive methods may be carried out by a processor running different software components, such as parts of the technical computing environment, on a host computer, the software components preferably using the mechanisms of the technical computing environment or of the operating system of the host computer to exchange data and/or cause the execution of one or more further software components. The host computer may be realized as a single standard computer comprising a processor, in particular a multicore general-purpose microprocessor, a display device and an input device, for example, a mouse and keyboard, graphical user interface, etc. The host computer system may comprise one or more servers comprising one or more processing elements, the servers being connected to a client comprising a display device and an input device via a network. Thus, the technical computing environment may be executed partially or completely on a remote server, such as in a cloud computing setup. A graphical user interface of the technical computing environment may be displayed on a portable computing device, in particular a computing device with a touch screen interface. In this case, it is particularly advantageous when the computations for executing the block diagram are carried out on a remote server. The technical computing environment may comprise a graphical user interface for modifying the block diagram and a simulation engine for executing the block diagram, so that the dynamical system described by the block diagram can be simulated. The block diagram may comprise multiple blocks with input and/or output signals that are connected to output and/or input signals of other blocks. Each block may be an atomic functional unit or may be a hierarchical block that is composed of a plurality of subordinate blocks.

The term program can refer to the functionality to be performed by the electronic control unit; it may be represented as a block diagram, a source code generated from the block diagram, or as binary executable file resulting from a compilation of the generated source code.

Advantageously, the inventive method makes it possible to interactively enter alternative parameters and compare their effects by narrowing down to temporally interesting areas of a simulation without having to start a new simulation. This improves usability, since time-local variations can be compared “on the fly”.

In an example, receiving a pause command at a specific simulation time further comprises stepping back from the specific simulation time, so that the first time span and the second time span overlap at least partially. Stepping back is performed before changing the parameter. For example, stepping back may be performed via a graphical user interface (GUI). The GUI may be a part of the simulation environment or may be a separate component that communicates e.g., with the simulation environment via an application programming interface (API). In the GUI, a cursor may indicate a current simulation time, and stepping back may be controlled by dragging the cursor or pressing a button. The user can choose the amount of simulation time that is repeated in the next simulation.

In an example, Simulating the block diagram in the simulation environment comprises executing the block diagram in a Model-in-the-loop simulation mode. During a Model-in-the-Loop (MIL) simulation, the block diagram is executed in the simulation environment. It may directly be interpreted or some preprocessing may be performed for the simulation; however, there is no need to perform the different steps for generating source code from the block diagram. The simulation environment may comprise facilities for programmatically influencing the simulation, such as an API that may e.g., accept function calls to stop the simulation and/or step back in the simulation time. Alternatively, or additionally, the simulation environment may comprise a GUI for starting and stopping a simulation, as well as stepping back the simulation time. Displaying the logged signal values may comprise adding a marker indicating a stop of the simulation and/or adding a marker at the time when a simulation with the changed parameter value was started.

In an example, Simulating the block diagram in the simulation environment comprises generating source code and executing at least some of the blocks periodically is done via executing the source code in a Software-in-the-Loop simulation mode. Executing the block diagram in a Software-in-the loop (SIL) simulation mode may comprise compiling the generated source code in order to build a program and executing the built program on the host computer, logging or extracting the values of one or more of the variables of the program during execution, and displaying or storing the logged simulation results. Different blocks of the block diagram may be executed in different simulation modes; some blocks may be executed in MIL simulation mode while other blocks may be executed in SIL simulation mode. The signals between blocks in MIL and SIL mode may be routed via dedicated data transfer functions that may also provide data logging in addition to signal routing. By comparing signals resulting from a MIL simulation and a SIL simulation with the same stimuli, the influence of code generation options may be ascertained.

In an example, Simulating the block diagram in the simulation environment may comprise logging a current value of the signal at a first period and logging a current value of all state variables at a second period, wherein the second period is a multiple of the first period, and wherein Receiving a pause command at a specific simulation time further comprises stepping back from the specific simulation time in steps that correspond to the second period. For some blocks, the output signal may depend on the current state as described in one more state variables. For instance, the output signal from a delay block depends on the input signal received one or a plurality of time steps earlier; a unit delay block may comprise a single state variable, whereas longer delays may e.g. use multiple state variables or an array comprising multiple elements. By only storing the state variables in periods that correspond to multiple time steps, the amount of memory consumed may be considerably reduced.

In an example, Receiving a pause command at a specific simulation time, Receiving a new value for the at least one parameter, and Simulating the block diagram for a further time span are repeated multiple times, and the sets of signal values resulting from simulations with different parameter are stored in separate buffers. The inventive method may be extended to accommodate a plurality of simulation runs with different parameter values. Receiving a pause command may in each case comprise stepping back; stepping back may always be done before receiving changed parameters.

The example may further comprise displaying a graphical user interface indicating the available sets of signal values, receiving a choice of one or more sets of signal values, and displaying the chosen sets of signal values. For example, the graphical user interface (GUI) may comprise facilities to show an explanation and/or label for each set of signal values; this may e.g. comprise indicating the respective parameter value used in the simulation. The GUI may comprise elements allowing for a choice of the sets of signal values to be shown; such elements may e.g. comprise radio buttons that can be activated or deactivated.

The example may further comprise displaying a graphical user interface indicating the available sets of signal values, receiving an indication of a set of signal values to discard, and deleting the indicated set of signal values.

An aspect of the invention also concerns a non-transitory computer readable medium containing instructions that, when executed by a microprocessor of a computer system, cause the computer system to carry out the inventive method as described above or in the appended claims.

In a further aspect of the invention, a computer system is provided which comprises a processor, a random access memory, a graphics controller connected to a display, a serial interface connected to at least one human input device, and a nonvolatile memory, in particular a hard disk or a solid-state disk. The nonvolatile memory comprises instructions that, when executed by the processor, cause the computer system to carry out the inventive method.

The processor may be a general-purpose microprocessor that is customary used as the central processing unit of a personal computer or it may comprise one or a plurality of processing elements adapted for carrying out specific calculations, such as a graphics-processing unit. The processor may be replaced or complemented by a programmable logic device, such as a field-programmable gate array, which is configured to provide a defined set of operations and/or may comprise an IP core microprocessor.

The nonvolatile memory may comprise a cross compiler that is adapted to generate instruction for a target processor differing from the processor of the host computer, and the computer system may comprise an embedded system comprising a target processor is connected to the host computer. This allows for a processor-in-the-loop simulation, wherein simulating the program may comprise generating source code from the block diagram, compiling the source code with the cross compiler, transferring the binary executable file to the embedded system, running the binary executable file on the target processor, logging or extracting the values of one or more of the variables of the program during execution, and storing or displaying the logged values on the host computer.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is an exemplary diagram of a computer system;

FIG. 2 is an exemplary diagram of software components in a computer system;

FIG. 3 is an exemplary diagram of a method for generating production code from a block diagram;

FIG. 4 is an exemplary diagram of a method for testing the compliance of the executable with a model specifying the desired behavior;

FIG. 5 is a schematic view of an example of a SIL simulation;

FIG. 6 is a schematic diagram of a window displaying two sets of signal values corresponding to different parameter values; and

FIG. 7 is a schematic flow chart of an example of the invention.

### DETAILED DESCRIPTION

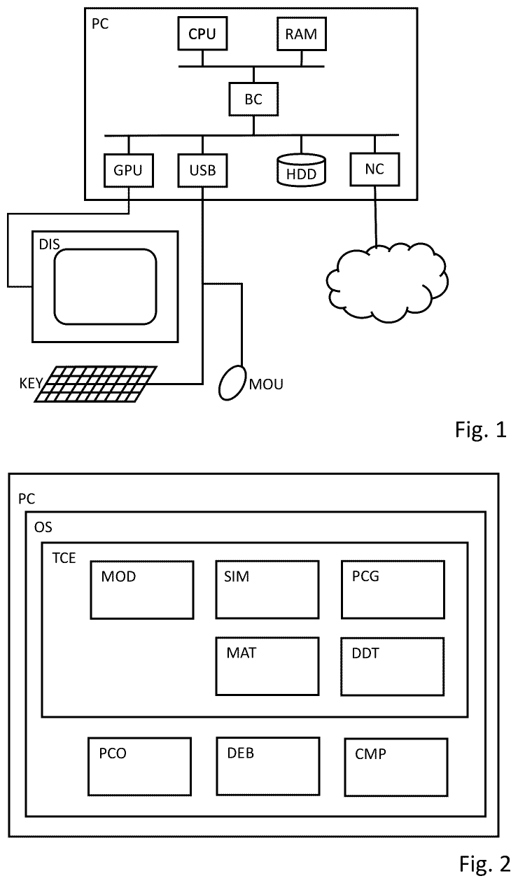

FIG. 1 illustrates an exemplary illustration of a computer system.

The shown example comprises a host computer PC with a display DIS and human interface devices such as a keyboard KEY and a mouse MOU.

The host computer PC comprises at least one processor CPU with one or multiple cores, a random access memory RAM and a number of devices connected to a local bus (such as PCI Express), which exchanges data with the CPU via a bus controller BC. The devices comprise e.g., a graphics-processing unit GPU for driving the display, a controller USB for attaching peripherals, a non-volatile memory HDD such as a hard disk or a solid-state disk, and a network interface NC. Preferably, the non-volatile memory can comprise instructions that, when executed by one or more cores of the processor CPU, cause the computer system to carry out a method according to one of the claims.

In further examples of the invention, as indicated by a stylized cloud, the host computer may comprise one or more servers comprising a plurality of processing elements, the servers being connected to a client comprising a display device and an input device via a network. Thus, the technical computing environment may be executed partially or completely on a remote server, such as in a cloud computing setup. A personal computer may be used as a client comprising a display device and an input device via a network. Alternatively, a graphical user interface of the technical computing environment may be displayed on a portable computing device, in particular a portable computing device with a touch screen interface.

FIG. 2 displays an example of the software components being executed on a computer system, which may be realized as a host computer PC with a standard microprocessor that runs a standard operating system OS such as Microsoft Windows or a Linux distribution.

On the host computer PC, a technical computing environment TCE such as MATLAB/Simulink of The MathWorks may be installed. Other examples of technical computing environments comprise LabVIEW of National Instruments or ASCET of ETAS. The technical computing environment TCE comprises a plurality of software components such as a model editor MOD and a simulation engine SIM. Additionally, the TCE may comprise a mathematical and/or script interpreter MAT that is adapted for carrying out calculations or modifying data. The TCE comprises a production code generator PCG that is adapted to produce production code from a model; further, it comprises a documentation generator and it may comprise a data definition tool DDT. The expression that a software component is comprised in the TCE is intended to encompass the case that the software component uses a specific mechanism of the TCE such as an application-programming interface of the TCE for exchanging data and/or instructions with other software components in the TCE. For example, a software component may be realized as or comprise an add-on such as a toolbox for the model editor.

The model editor MOD may provide a graphical user interface for creating and modifying block diagrams that describe the temporal behavior of a dynamic system. Additionally, blocks adapted for describing finite states and conditions for transitions between states may be used to model the dynamic system. A block may describe an atomic operation, such as an arithmetic calculation or a logic expression, or it may represent a subsystem that is described in more detail by an additional or partial block diagram in a subordinate hierarchical level. This need not imply that the partial block diagram is stored in a separate file, but rather that the functionality of a hierarchical block is defined by a plurality of blocks in a subordinate level. Alternatively, it may contain code in a higher-level programming language, in particular a dynamic language intended for mathematical programming, that realizes the block's functionality. Multiple blocks may be connected by signals for the exchange of data. For example, an initial block may receive a signal of type single as input signal, may modify the signal e.g., by adding a constant and may send an output signal of type double to a further block. It may be said that the further block is downstream of the initial block because they are connected by a signal path so that data flows from the initial block to the further block.

The simulation engine SIM may be adapted to execute a block diagram created in the model editor MOD in order to observe the temporal behavior of the dynamic system described by the block diagram. The execution of a block diagram may also be called a model-in-the-loop simulation of the dynamic system and may be carried out using high-precision operations in order to observe the behavior more closely and to create reference data.

The production code generator PCG allows for creating production code from one or more blocks in a block diagram. Production code may be optimized for readability, traceability, safety, low-energy consumption, execution speed and/or memory requirements. For example, the code generator can provide a user interface for setting a plurality of options for adapting the customization of the generated code. Customization options may include target-specific optimizations for the microcontroller of the embedded system and enforcing compliance of the generated code to a specific standard, such as the MISRA C guidelines. A particularly preferred production code generator PCG may be TargetLink of dSPACE.

The data definition tool DDT provides a local or remote database for storing definitions and parameters as well as an application-programming interface for automatic exchange of the data between different software components. The term “database” is to be understood preferably in a broad sense, so that a file with a tree structure may be considered a database. A data definition tool allows for a clean separation of the model of the dynamic system given in the block diagram from implementation-specific details stored in the database. When a complex model is structured in different sub-models, data in different sub-models may be linked. By storing corresponding information in the data definition tool, these dependencies may be automatically resolved. Additionally, by exchanging data with a software architecture tool, such as SystemDesk of dSPACE, the data definition tool DDT can be used as part of a higher-level tool chain, in particular to generate product code compliant to the AUTOSAR standard. A preferred data definition tool is TargetLink Data Dictionary of dSPACE.

Other software components such as a production code compiler PCO, a debugger DEB or a comparison tool CMP may also be installed on the computer. These software components may be interfaced to each other and/or the technical computing environment using standard mechanisms of the underlying operating system OS. The compiler PCO may generate an executable for the microprocessor of the PC, or it may generate an object code for the microcontroller of the embedded system. Additionally, it may be configured to generate additional debugging information and to include it in the executable. In this way, the debugger DEB can e.g., be used for observing the value of a signal during a software-in-the-loop simulation of the generated production code. Depending on the intended use, the observed values may be directly displayed to the user and/or they may be logged in a memory, e.g., in RAM, in a file or a database.

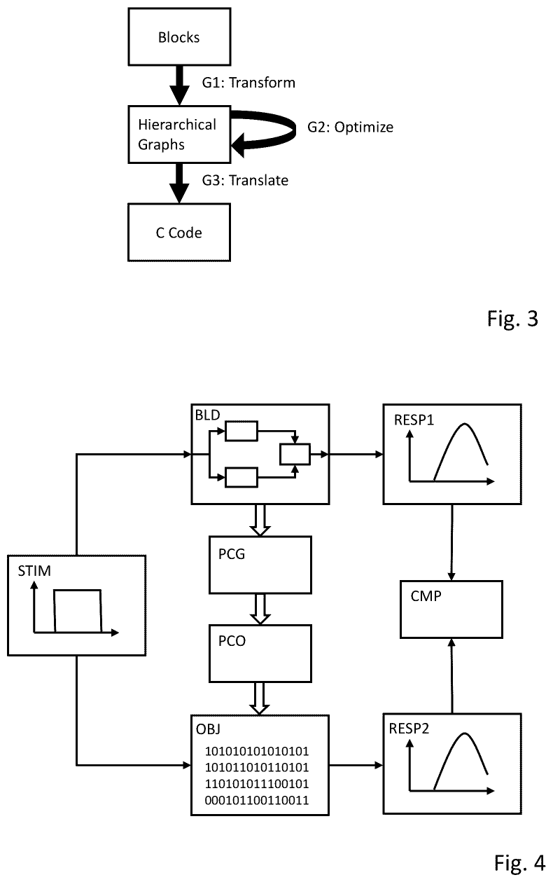

FIG. 3 illustrates an example of the generation of production code from one or more blocks in a block diagram. The following steps can be carried out by a microprocessor on the host computer; alternatively, a client server setup may be used so that computationally expensive steps are carried on a remote server containing a plurality of microprocessors.

In a first step G1, the selected one or more blocks (or, if selected, the entire block diagram) and related input data are transformed to an intermediate representation such as one or more hierarchical graphs. These hierarchical graphs may in particular comprise a data flow graph, a control flow graph and/or a tree structure. Related input data may e.g., be extracted from a database associated with the block diagram. This may encompass situations where elements of the block diagram are created based on information from a data definition tool, or where settings relevant for the production code generation are retrieved from the data definition tool.

In a second step G2, the hierarchical graphs are optimized in order to reduce the number of variables required and/or the number of operations or instructions to be carried out. This optimization may comprise a plurality of intermediate steps on further intermediate representations between block level and production code level. In each step, an initial set of hierarchical graphs or an intermediate language is converted to a modified set of hierarchical graphs or an intermediate language while applying one or more optimization rules. A number of strategies such as constant folding or elimination of dead code may be applied during optimization.

In a third step G3, the optimized intermediate representations such as optimized hierarchical graphs are translated to code in a high-level or low-level programming language, for example, C code. The code may be further optimized in this step and restricted to a subset of the linear or parallel programming language, the control and dataflow structures may be restricted to precisely specified variants, the scope of functions and data may be restricted according to accurately specified rules. Alternatively, or in addition, additional information may be added to the code, e.g. in the form of comments, to enhance readability or help in debugging the code.

During or after the code generation, information on the current block diagram or the code generation, especially results of the code generation, may again be stored in a database such as the data definition tool. This information may e.g., be used to initialize the simulation engine, to influence a compilation process with a production code compiler, or to export production code information for use in other tools/process, like e.g. calibration and measurement information in ASAP2 format (in particular a variable description file) or AUTOSAR XML information. For example, a documentation can be generated automatically after production code generation has been finished.

Hardware-level code or a configuration for a programmable hardware device may be created from the blocks describing the control program.

FIG. 4 displays an example of a method for compiling and testing a control program.

The model editor MOD of the TCE can comprise a graphical user interface for modifying a block diagram BLD, which may comprise a plurality of blocks interconnected by signal paths. Each block may be an atomic block providing a specific functionality or it may represent a hierarchical block such as a subsystem, which comprise a plurality of subordinate blocks that are shown in a lower hierarchical level. Blocks may be connected by signals which may be of scalar or composite type, and which can be represented by arrows indicating the direction of the data flow. In the shown example, the block diagram comprises three blocks, an input port for receiving an input signal and an output port for sending an output signal. For example, the block diagram describes the predetermined or intended behavior of a control program. Upon activation of the simulation engine in the technical computing environment, the block diagram BLD is executed, and results are calculated for each time step. The block diagram may be interpreted directly, or it may be converted to an intermediate form that allows for a faster execution in the simulation engine.

A number of test cases for the control program can be deduced from the specification and intended application of the control program. Advantageously, a test case comprises a stimulus STIM sent as an input signal to the control program and a corresponding response RESP received as an output signal from the control program. In the shown example, the stimulus STIM is represented by a diagram depicting a particular temporal behavior of the input signal. When the control program is executed in the simulation engine on the host computer, operations corresponding to the block diagram BLD are carried out for a plurality of time steps. During each time step, the current value of the stimulus STIM is fed to the appropriate input ports of the block diagram, the block diagram BLD is being executed in the simulation engine, so that signals are being manipulated and a new internal state of the model may be reached. By simulating the model given in the block diagram for a predetermined duration and by recording the output signal, a response RESP1 can be determined in a model-in-the-loop simulation. A model-in-the-loop simulation mode may be used for verifying that the block diagram executed in the simulation engine actually describes the intended behavior of the control program. All arithmetic calculations can be carried out with high-precision operations, e.g., using the floating-point data type double for the variables. As a result, the simulation is sufficiently accurate to use the recorded output signals as reference data.

Once correctness of the model has been established and reference data has been stored, the blocks corresponding to the control program may be converted to source code via the production code generator PCG. The generated production code is then compiled to object code or an executable using the production code compiler PCO; an object code is binary data that contains instructions for a particular processor. When the object code is combined with additional information for the operating system of the host computer, an executable for the host computer is formed. Settings applied during the code generation may comprise a conversion to lower-precision operations that are computationally more efficient, e.g., integer instructions for fixed-point calculations, so that the control program later can be executed in real-time on the microcontroller of an embedded system.

In order to verify that the calculations of the generated code are sufficiently accurate and match the behavior of the blocks in the graphical model, a software-in-the-loop simulation may be carried out. The object code or the executable OBJ, which may be in the form of a DLL, contains calculations corresponding to the block diagram. During a predetermined duration, a stimulus STIM is fed to the object code or executable OBJ, and the output signals are recorded to obtain a response RESP2. Generally, multiple variables may be logged while running the simulation; this may comprise adding log macros to the program code prior to the simulation and determine a basic data type of an enumeration signal when initializing the simulation.

The response RESP1 of the model-in-the-loop simulation may be compared to the response RESP2 of the generated code in a comparison tool CMP, so that a number of checks for compliance to predetermined conditions may be carried out. The output signals may be compared point by point; in particular, the absolute difference between a data point in RESP1 and the corresponding data point in RESP2 may be calculated. By comparing the differences to a threshold indicating a maximum permissible difference, the correctness of the optimizations applied when generating and compiling the code can be verified.

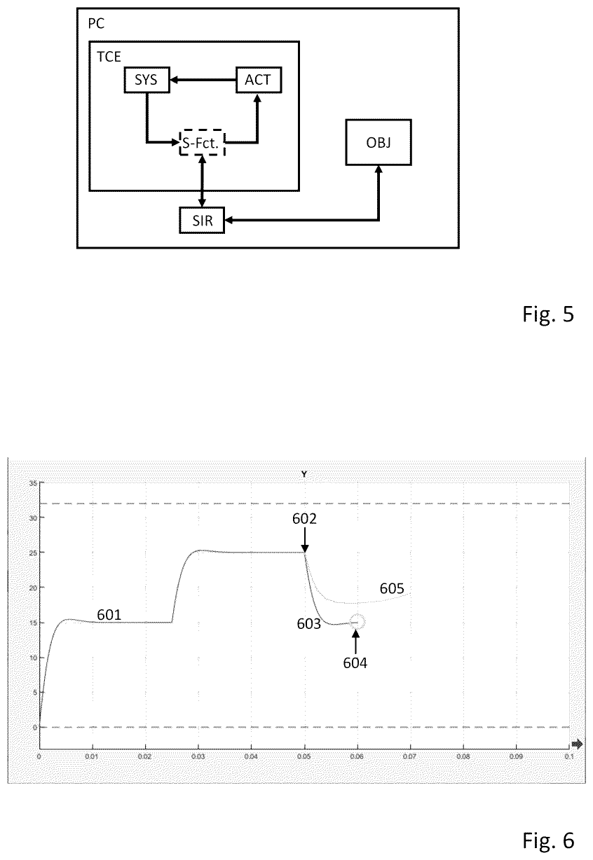

FIG. 5 illustrates an example of a software-in-the-loop (SIL) simulation, i.e., a simulation for which production code is generated and compiled, the resulting executable then being run on the host computer PC, as indicated by the outermost rectangle.

The technical computing environment TCE comprises a simulation engine for executing block diagrams; the simulation engine may in particular comprise a solver. At least one block or subsystem SYS corresponding to a model of the plant, i.e., the dynamical system to be controlled, is executed in the simulation engine. The plant model block SYS may comprise an arbitrary number of subordinate blocks. At least one signal, e.g. a sensor output, is sent from the plant model block to a communication function S-Fct., which is integrated with the simulation engine of the technical environment. In the picture, signals are represented by arrows from a sending block to a receiving block. The communication function may advantageously replace in the simulation engine the one or more blocks for which a software-in-the-loop simulation mode has been selected and provide a mechanism for exchanging signals. The communication function may be generated by the technical computing environment, in particular based on the specification of the one or more blocks with respect to input or output ports and/or signals received or sent by these blocks.

The communication Function S-Fct. provides for an exchange of signals, which may be represented by the value of a variable, between the simulation engine SIM and a signal router SIR. Thus, for a SIL simulation, or a combined MIL/SIL simulation, the simulation environment may comprise the simulation engine SIM and the signal router SIR.

The signal router SIR allows for exchanging signals between the simulation engine and/or one or more executables; it may only need to be connected to the communication function S-Fct. for a transfer of signals. The signal router may be realized as a standalone executable or as a library routine, in particular a DLL, in the operating system of the host computer. The signal router may comprise a buffer and/or a logging mechanism for the one or more signals to be exchanged.

An executable OBJ for the control program may be created from the one or more selected blocks via the production code generator PCG and the production code compiler PCO. The executable OBJ containing the compiled production code may e.g., be realized as a dynamic link library in the operating system of the host computer. Input/Output signals of the executable OBJ are sent/received via the signal router and the communication function and transferred from/to the simulation environment. Also, other data interesting for analysis during this testing process may be collected and transferred from/to the executable OBJ, for example coverage data. In the shown example, the block diagram comprises an actuator model block ACT, which modifies the output signals of the executable OBJ and sends the resulting signal to the plant model SYS. As a result, a closed-loop simulation of the complete dynamical system comprising plant and controller can be performed.

The simulation environment may comprise a host environment for executing the control program OBJ on the host computer. The signal router can allow for static or on-the-fly switching between different connected executables by redirecting the exchanged signals. Further, it is possible to simulate several subsystems or submodels in a software-in-the-loop simulation mode at once by routing the corresponding signals for each through the signal router.

When a software-in-the-loop simulation is performed, the effect of converting high-precision operations to lower-precision operations on the accuracy of the control can be observed in order to check the correctness of the code generator. Using the mechanisms of the operating system of the host computer, a plurality of dedicated programs such as a stand-alone debugger may be interfaced to the executable OBJ for a fast and extensive analysis of the control program implemented in the production code.

FIG. 6 displays a is a schematic diagram of a window displaying two sets of signal values corresponding to different parameter values. In the diagram, the simulation time extends along the X axis whereas the signal value determines height in the Y axis. Permissible limits for the signal values may be indicated as dotted lines.

Starting at a simulation time 0, a simulation, in particular a MIL simulation, has been carried out, resulting in the curve 601 displaying the signal values over time. Following simulation time 602, two sets of signal values corresponding to different parameter values are shown. One simulation with a first parameter value resulted in the curve 605. Another simulation with a second parameter value resulted in the curve 603. The current simulation time and/or the current signal value may be indicated by a marker 604.

The user may choose to stop the simulation (e.g. by pressing a predefined key or via a GUI that is not shown in the diagram) and to step back in simulation time (e.g. by dragging the marker 604 to the simulation time 602). Running the simulation may be resumed after changing the parameter value. The user may stop the simulation again as desired and may step back multiple times to the point 602, so that different signal values resulting from different parameter values may be logged and displayed for comparison. The window comprising the diagram for the different signal values may comprise other GUI elements for starting and stopping the simulation, changing parameter values and/or adapting the lines or symbols that are displayed for the sets of signal values.

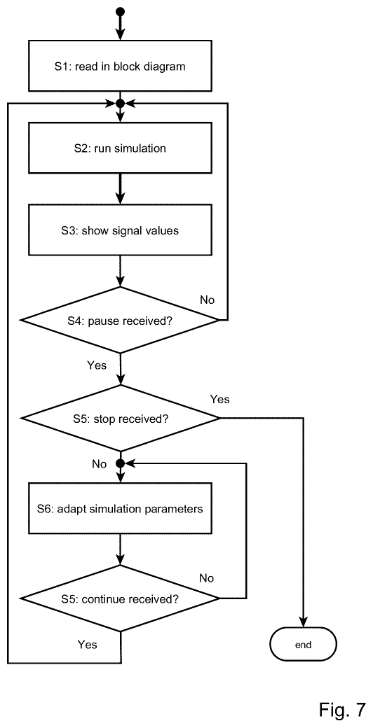

FIG. 7 displays a flow chart of an example of the invention. The steps may be carried out by one or more processors of a host computer running a technical computing environment.

In step S1 (read in block diagram), the block diagram comprising a model of the control program to finetune is read in. This may comprise determining parameter values based on the data definition tool and/or executing a script in the script interpreter.

In step S2 (run simulation), the block diagram is simulated for a first time span in the simulation environment. Simulating the block diagram comprises periodically executing at least some of the blocks and periodically logging a current value of the signal. The signal values may be stored in a dedicated buffer. In principle, more than one relevant signal may be logged during the simulation; for simplicity, the current discussion focusses on one signal. Extending the method to multiple signals resulting simultaneously from the simulation is straightforward.

In step S3 (show signal values), the values of the signal as a function of the simulation time are displayed. If more than one set of signal values has already been logged and stored in a buffer, both the values of the signal from the first time span and the values of the signal from the second time span are displayed. The values from the second time span are displayed graphically different from those of the first time span. This can e.g., be done using a line with a different color. For multiple simultaneous signals, multiple display windows may be used.

In step S4 (pause received?), the processor checks whether a pause command was received at a specific simulation time. Receiving a pause command at a specific simulation time may further comprise stepping back from the specific simulation time, so that the first time span and the second time span overlap at least partially. If no pause command was received, the currently running simulation is continued in step S2. Once a pause command has been received, execution continues at step S5.

In step S5 (stop received?), the processor checks whether the user chose to abort the simulation. This may be performed by pressing a corresponding button in the graphical user interface (GUI) of the simulation environment. Once an abort command is received, the sets of signal values already logged may be stored in one or more files before the method stops. When no abort command is received, execution continues at step S6.

For example, the simulation environment provides a graphical user interface (GUI) for changing a parameter value. The GUI may have the form of a dedicated window or of context menus or block dialogs attached to blocks in the block diagram. Before giving the continue command, the user may have changed at least one parameter. In step S6 (adapt simulation parameters), a new value for the parameter value is received and applied to the simulation. This may comprise changing several other simulation parameters that depend on the received parameter. For simulations having multiple parameters, more than one parameter value may be changed.

In step S5 (continue received?), the processor checks whether a continue command was received. When a new value for the at least one parameter has been received the continued simulation will show an at least somewhat different behavior. When a continue command is received, execution continues at step S2, now resulting in a different set of signal values that is separately logged.

Those skilled in the art will appreciate that the order of at least some of the steps of the inventive method may be changed without departing from the scope of the claimed invention. While the present invention has been described with respect to a limited number of embodiments, those skilled in the art will appreciate numerous modifications and variations therefrom. It is intended that the appended claims cover all such modifications and variations as fall within the true spirit and scope of the present invention.

What is claimed is:

1. A method for simulating a program, the program being modeled as a plurality of blocks in a block diagram, the block diagram comprising at least one signal emitted by one of the blocks and at least one parameter that influences a value of the signal, the block diagram being executed in a technical computing environment, the technical computing environment comprising a model editor and a simulation environment, the method being executed by at least one processor of a host computer, the method comprising:
opening the block diagram in the model editor;
simulating the block diagram for a first time span in the simulation environment, comprising periodically executing at least some of the blocks and periodically logging a current value of the signal;
displaying the values of the signal as a function of the simulation time;
receiving a pause command at a specific simulation time;
receiving a new value for the at least one parameter;
simulating the block diagram for a second time span in the simulation environment, comprising periodically executing at least some of the blocks and periodically logging a current value of the signal; and
displaying both the values of the signal from the first time span and the values of the signal from the second time span, wherein the values from the second time span are displayed graphically different from those of the first time span.

2. The method of claim 1, wherein receiving a pause command at a specific simulation time further comprises stepping back from the specific simulation time, so that the first time span and the second time span overlap at least partially.

3. The method of claim 1, wherein simulating the block diagram in the simulation environment comprises executing the block diagram in a Model-in-the-loop simulation mode.

4. The method of claim 1, wherein simulating the block diagram in the simulation environment comprises generating source code and executing at least some of the blocks periodically is done via executing the source code in a Software-in-the-Loop simulation mode.

5. The method of claim 4, wherein simulating the block diagram in the simulation environment comprises logging a current value of the signal at a first period and logging a current value of all state variables at a second period, wherein the second period is a multiple of the first period, and wherein receiving a pause command at a specific simulation time further comprises stepping back from the specific simulation time in steps that correspond to the second period.

6. The method of claim 1, wherein receiving a pause command at a specific simulation time, receiving a new value for the at least one parameter, and simulating the block diagram for a further time span are repeated multiple times, and wherein the sets of signal values resulting from simulations with different parameter are stored in separate buffers.

7. The method of claim 6, further comprising displaying a graphical user interface indicating the available sets of signal values, receiving a choice of one or more sets of signal values, and displaying the chosen sets of display values.

8. The method of claim 6, further comprising displaying a graphical user interface indicating the available sets of signal values, receiving an indication of a set of signal values to discard, and deleting the indicated set of signal values.

9. A non-transitory computer readable medium containing instructions that, when executed by a microprocessor of a computer system, cause the computer system to carry out the method according to claim 1.

10. A computer system comprising a host computer, the host computer comprising:
a microprocessor;
a random access memory;
a graphics controller connected to a display;
a serial interface connected to at least one human input device; and
a memory comprising instructions that, when executed by the microprocessor, cause the computer system to carry out the method according to claim 1.

11. The computer system according to claim 9, wherein the memory is a nonvolatile memory, a hard disk or solid state disk.
